(19) United States
(12) Patent Application Publication
(10) Pub. No.: US 2007/0269941 A1
(43) Pub. Date: Nov. 22, 2007

(54) Method of forming semiconductor device having a dopant-doped region

(76) Inventor: Seung-Chul Lee, Seongnam-si (KR)

Correspondence Address: MILLS & ONELLO LLP, ELEVEN BEACON STREET, SUITE 605, BOSTON, MA, 02108, US

(21) Appl. No.: 11/655,575

(22) Filed: Jan. 19, 2007

(30) Foreign Application Priority Data
Jan. 20, 2006 (KR) 10-2006-0006234

(51) Int. Cl. H01L 21/336

(52) U.S. Cl. 438/155; 438/162; 257/E21.411

(57) ABSTRACT

There is provided a method of forming a semiconductor device including a dopant-doped region. Lattice defect inducing element ions are implanted to a semiconductor channel layer to form a lattice defect region. After dopants are implanted to the lattice defect region, an annealing process is performed to form the dopant-doped region.

### CROSS-REFERENCE TO RELATED APPLICATIONS

This U.S. non-provisional patent application claims priority under 35 U.S.C. §119 to Korean Patent Application No. 10-2006-0006234, filed on Jan. 20, 2006, the entire contents of which are hereby incorporated by reference.

### BACKGROUND OF THE INVENTION

1. Field of the Invention

The present invention relates to a method of forming a semiconductor device, and particularly, to a method of forming a semiconductor device having a dopant-doped region.

2. Description of the Related Art

Generally, a semiconductor device includes conductive dopant-doped regions that are obtained by doping a semiconductor with p-type dopants or n-type dopants. The dopant-doped regions can be mainly used as source/drain regions of a metal-oxide semiconductor field-effect transistor (MOSFET) (hereinafter simply referred to as “transistor”). Of course, the dopant-doped region can be used as a well and/or one end of a PN diode.

A general method of forming the dopant-doped region will now be briefly described. Dopants are implanted into a semiconductor substrate by an ion implanting method, and then the implanted dopants are activated by an annealing process, so that a dopant-doped region having conductivity can be formed.

As semiconductor devices become increasingly integrated, the dopant-doped region is also getting smaller. Forming the small dopant-doped region can cause difficulties in the annealing process for activating the implanted dopants. For example, when a process temperature of the annealing process is increased, the implanted dopants are diffused, resulting in an increase in volume of the dopant-doped region. Therefore, it is required to limit the process temperature of the annealing process and thus reduce the volume of the dopant-doped region.

However, such limitations on the process temperature of the annealing process can result in a decrease in the amount of dopants activated within the dopant-doped region. As the amount of dopants being activated decreases, the electrical resistance of the dopant-doped region increases, causing various types of problems. For example, the increase in resistance in source/drain regions causes a decrease in the amount of turn-on currents of a transistor. For those reasons, characteristics of the semiconductor device can be degraded, or malfunctioning of the semiconductor device can occur.

Particularly, when the dopant within the dopant-doped region is boron, the amount of dopants activated within the dopant-doped region can decrease further. The activation level of boron is lower than that of arsenic and phosphorous. In other words, boron requires more energy for the activation than arsenic and phosphorous. Accordingly, the characteristic degradation of a PMOS transistor including source/drain regions doped with boron can be worsened.

### SUMMARY OF THE INVENTION

The present invention provides a method of forming a semiconductor device including dopant-doped regions optimized for high integration.

The present invention also provides a method of forming a semiconductor device that can increase the amount of dopants activated within dopant-doped regions.

The present invention also provides a method of forming a semiconductor device that can increase the amount of dopants activated within dopant-doped regions at a limited annealing temperature.

In accordance with one aspect of the present invention, provided is a method of forming semiconductor devices. The method includes implanting lattice defect inducing element ions into a semiconductor channel layer of a substrate to form a lattice defect region, and implanting dopant ions into the lattice defect region to form a dopant-implanted region. An annealing process is performed on the dopant-implanted region to form a dopant-doped region.

The lattice defect inducing element ions can be of an element that is irrelevant to an electrical characteristic of the dopant-doped region.

The lattice defect inducing element can be one selected from the group comprising silicon, carbon, nitrogen, fluorine, germanium, and a combination thereof.

The substrate can include a semiconductor substrate, a buried insulating layer, and a semiconductor channel layer that are sequentially stacked.

The method can further include forming a gate pattern including a gate insulating layer and a gate electrode that are sequentially stacked on the semiconductor channel layer.

In this case, the lattice defect inducing element ions can be implanted using the gate pattern as a mask, and the lattice defect region can be formed at both sides of the gate pattern in the semiconductor channel layer

The method can further include forming spacers on both sidewalls of the gate pattern before the forming of the lattice defect region. In this case, the lattice defect inducing element ions can be implanted using the gate pattern and the spacers as a mask.

In accordance with another aspect of the present invention, provided are methods for forming semiconductor devices, including forming an interlayer insulating layer on a substrate and forming a semiconductor channel layer on the interlayer insulating layer. A gate pattern including a gate insulating layer and a gate electrode that are sequentially stacked on the semiconductor channel layer is formed. Lattice defect inducing element ions are implanted into the semiconductor channel layer using the gate pattern as a mask to form a lattice defect region. Dopant ions are implanted into the lattice defect region using the gate pattern as a mask to form a dopant-implanted region, and an annealing process is performed on the substrate having the dopant-implanted region to form a dopant-doped region.

The lattice defect inducing element ions can be of an element that is irrelevant to an electrical characteristic of the dopant-doped region.

The lattice defect inducing element can be one selected from the group comprising silicon, carbon, nitrogen, fluorine, germanium, and a combination thereof.

The dopant ions can be boron ions.

The method can further include forming spacers on both sidewalls of the gate pattern before the forming of the lattice defect region. In this case, the lattice defect inducing element ions are implanted using the gate pattern and the spacers as a mask.

The method can further include patterning the interlayer insulating layer to form a contact hole exposing a predetermined region of the substrate and forming an epitaxial contact filling the contact hole and contacting the substrate and the semiconductor channel layer. The semiconductor channel layer can be formed in a single crystalline state.

The lattice defect region can be further formed at an upper portion of the epitaxial contact. In this case, the method can further include, before the performing of the annealing process, removing the semiconductor channel layer on the epitaxial contact and at least the upper portion of the epitaxial contact to form a recess region.

The method can further include forming an upper insulating layer on an entire surface of the substrate having the doped region, the upper insulating layer filling the recess region and forming a node contact penetrating at least the upper insulating layer and overlapping the recess region, the node contact being electrically connected to a side surface of the dopant-doped region and the substrate exposed by the contact hole.

Forming the semiconductor channel layer can include forming an amorphous semiconductor channel layer on the interlayer insulating layer, the amorphous semiconductor channel layer contacting the epitaxial contact, and performing a thermal treatment on the amorphous semiconductor channel layer to form the semiconductor channel layer in a single crystalline state.

Forming of the epitaxial contact and the semiconductor channel layer can include forming a single crystalline epitaxial layer by an epitaxial growing process, the signal crystalline epitaxial layer filling the contact hole and covering the interlayer insulating layer, and planarizing an upper surface of the epitaxial layer. In this case, a portion of the planarized epitaxial layer that fills the contact hole is the epitaxial contact, and a portion of the planarized epitaxial layer that is disposed on the interlayer insulating layer and contacts the epitaxial contact is the semiconductor channel layer.

The method can further comprise, before the forming of the interlayer insulating layer forming a lower gate pattern on the substrate and forming lower source/drain regions at both sides of the lower gate pattern in the substrate. In this case, the interlayer insulating layer covers the lower gate pattern and the lower source/drain regions, and the contact hole exposes the lower source/drain regions.

The lower gate pattern and the lower gate source/drain regions can comprise a lower transistor corresponding to a drive transistor of an SRAM cell, and the gate pattern and the dopant-doped region can comprise an upper transistor corresponding to a load transistor of the SRAM cell.

### BRIEF DESCRIPTION OF THE DRAWINGS

The accompanying drawings illustrate embodiment(s) of or related to the invention and together with the description serve to explain the principle of the invention. In the drawings:

FIGS. 1 through 4 are cross-sectional views for describing a first embodiment of a method of forming a semiconductor device including a dopant-doped region, according to a first aspect of the present invention; and

FIGS. 5 through 10 are cross-sectional views for describing a second embodiment of a method of forming a semiconductor device including a dopant-doped region, according to another aspect of the present invention.

### DETAILED DESCRIPTION OF ILLUSTRATIVE EMBODIMENTS

Reference will now be made in detail to the illustrative embodiments, examples of which are illustrated in the accompanying drawings. However, the present invention is not limited to the embodiments illustrated herein after. In the drawings, the thicknesses of layers (or films) and regions are exaggerated for clarity, and proportions of such layers (or films) and regions are not to scale, but such thicknesses and proportions would be known to those of skill in the art.

It will be understood that, although the terms first, second, etc. can be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

It will be understood that when a layer (or film) is referred to as being “on” another layer (or film) or substrate, it can be directly on the other layer (or film) or substrate, or intervening layers (or films) can also be present. Other words used to describe the relationship between elements should be interpreted in a like fashion (e.g., “between” versus “directly between,” “adjacent” versus “directly adjacent,” etc.). Also, like reference numerals in the drawings denote like elements, and thus their overlapping description will be omitted for conciseness.

### First Illustrative Embodiment

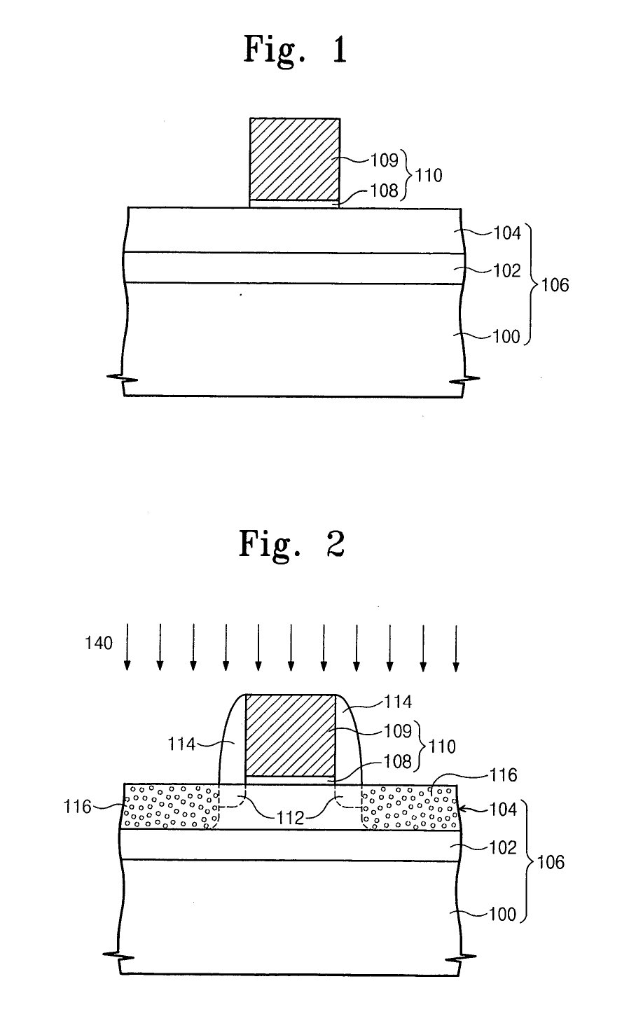

FIGS. 1 through 4 are cross-sectional views for describing a first embodiment of a method of forming a semiconductor device including a dopant-doped region according to an aspect of the present invention.

Referring to FIG. 1, a substrate 106 including a semiconductor channel layer 104 is prepared or formed. The substrate 106 preferably includes a semiconductor substrate 100, a buried insulating layer 102, and the semiconductor channel layer 104. That is, the substrate 106 is an SOI (silicon on insulator) substrate that has a layered structure where the buried insulating layer 102 is interposed between the semiconductor channel layer 104 and the semiconductor substrate 100, in this embodiment.

Alternatively, the substrate 106 can include only the semiconductor substrate 100 and the semiconductor channel layer 104. That is, the semiconductor channel layer 104 can contact a top surface of the semiconductor substrate 100 without the buried insulating layer 102 interposed therebetween. In this case, the semiconductor channel layer 104 can be formed on the semiconductor substrate 100.

Preferably, the semiconductor channel layer 104 is in a single crystalline state. A gate pattern 110 is formed on the semiconductor channel layer 104. The gate pattern 110 includes a gate insulating layer 108 and a gate electrode 109 that are sequentially stacked. The gate pattern 110 can further include a capping insulating pattern (not shown) disposed on the gate electrode 109. The gate insulating layer 108 can be an oxide layer, particularly, a thermal oxide layer. The gate electrode 109 is formed of a conductive material. For example, the gate electrode 109 can be formed of a conductive material selected from a group comprising doped polysilicon, metal (e.g., tungsten, molybdenum, etc), conductive metal nitride (e.g., titanium nitride, tantalum nitride, etc), metal silicide (e.g., tungsten silicide, cobalt silicide, or the like), and a combination thereof.

Referring to FIG. 2, first dopant ions are implanted into the semiconductor channel layer 104 using the gate pattern as a mask 110, to form a first dopant-implanted region 112. Next, spacers 114 are formed on both sidewalls of the gate pattern 110. The spacers can include at least one of an oxide layer, a nitride layer and an oxide nitride layer, all of which are insulating materials. The first dopant-implanted region 112 can correspond to a lightly doped region of a lightly-doped diffusion (LDD) source/drain region and/or an extended portion of an extended source/drain region.

Lattice defect inducing element ions 140 are implanted into the semiconductor device channel layer 104 using the gate pattern 110 and the spacers 114 as a mask, to form a lattice defect region 116. The lattice defect inducing element ions induce lattice defects of semiconductor lattices within the semiconductor channel layer 104. More specifically, the lattice defect inducing ions are implanted to weaken a bonding force of the semiconductor atoms within the semiconductor channel layer 104. Also, the lattice defect inducing element ions move away the semiconductor atoms from a lattice to form a plurality of vacancies. Thus, the lattice defect region 116 includes a plurality of vacancies, and includes the semiconductor atoms whose bonding forces are weakened.

Preferably, the lattice-defect inducing element ions 140 are of an element that is irrelevant to electrical characteristics of the dopant-doped region. That is, the lattice-defect inducing element does not affect the resistance of the dopant-doped region when present in the dopant-doped region. For example, the lattice-defect inducing element can be one selected from a group comprising silicon, carbon, nitrogen, fluorine, germanium, and a combination thereof.

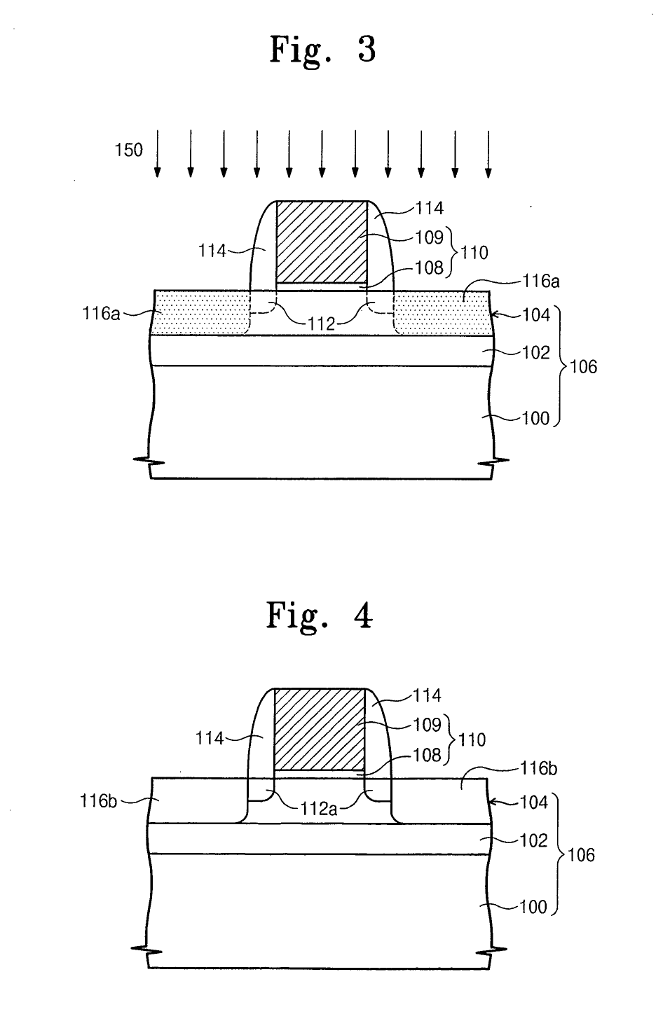

Referring to FIG. 3, second dopant ions 150 are implanted into the lattice defect region 116 using the gate pattern 110 and the spacers 114 as a mask to form a second dopant-implanted region 116a. The second dopant ions occupy the vacancies of the lattice defect region 116, and are substituted for the semiconductor atoms having weakened bonding forces. Therefore, as compared to the prior art, much more second dopants can be substituted for the semiconductor atoms in the second dopant-implanted region 116a.

The second dopant ions can be n-type dopant ions such as arsenic (As) ions, phosphorous (P) ions, or the like. Alternatively, the second dopant ions can be p-type dopant ions such as boron ions or the like. In either case, the first dopants are the same type as the second dopants. Doses of the first dopant ions can be lower than doses of the second dopant ions. In this case, the first dopant-implanted region 112 corresponds to a lightly doped region of an LDD source/drain region. The doses of the first dopant ions can be almost the same as those of the second dopant ions. In this case, the first dopant-implanted region corresponds to an extended portion of an extended source/drain region.

Referring to FIG. 4, an annealing process is performed on the first and second dopant-implanted regions 112 and 116a to form first and second doped regions 112a and 116b. The dopants within the first and second dopant-implanted regions 112 and 116a are activated by the annealing process. Thus, the first and second dopant-doped regions 112a and 116b have electric conductivity. The lattice defects within the second dopant-implanted region 116a are removed by the annealing process. The annealing process can be a rapid thermal annealing process or a laser annealing process, as examples.

According to the method of forming the aforementioned semiconductor device, the lattice defect inducing element ions are introduced before the second dopant ions are implanted, so that the lattice defect region 116 including the plurality of vacancies and/or the semiconductor atoms having the weakened bonding force is formed. Accordingly, as compared to the prior art, much more second dopants are substituted for the semiconductor atoms.

Consequently, as compared to the prior art, the amount of dopants activated in the second dopant-doped region 116b greatly increases, so that the second dopant-doped region 116b with an excellent electrical characteristic (e.g., small electrical resistance, or the like) can be formed. As a result, a semiconductor device optimized for high integration can be implemented. Particularly, when boron having a relatively low activation level is used as the second dopants, the amount of boron activated within the second dopant-doped region 116b can be significantly increased, as compared to the prior art.

Also, such an increase in the amount of activated dopants of the implanted second dopants consequently decreases the amount of dopants inactivated within the dopant-doped region 116b. As a result, defects of the dopant-doped region 116b that can be caused by the inactivated dopants can be reduced.

In accordance with this embodiment, a sufficient amount of activated dopants is ensured even without increasing a process temperature of the annealing process. Thus, the diffusion of the second dopants is minimized, so that the size of second dopant-doped region 116b can also be minimized. Furthermore, the second dopant-doped region 116b can be formed on the buried insulating layer 102. Accordingly, surplus elements (e.g., lattice defect inducing elements and/or surplus semiconductor atoms) between lattices within the second dopant-doped region 116b can be prevented from being diffused by the thermal supply in the following processes. If the surplus elements are diffused, the second dopants can be diffused together therewith.

The lattice defect region 116, the second dopant-implanted region 116a, and the second dopant-doped region 116b can be formed right after the gate pattern 110 is formed. In this case, the processes of implanting the first dopant ions and forming of the spacers 114 need not be performed.

### Second Embodiment

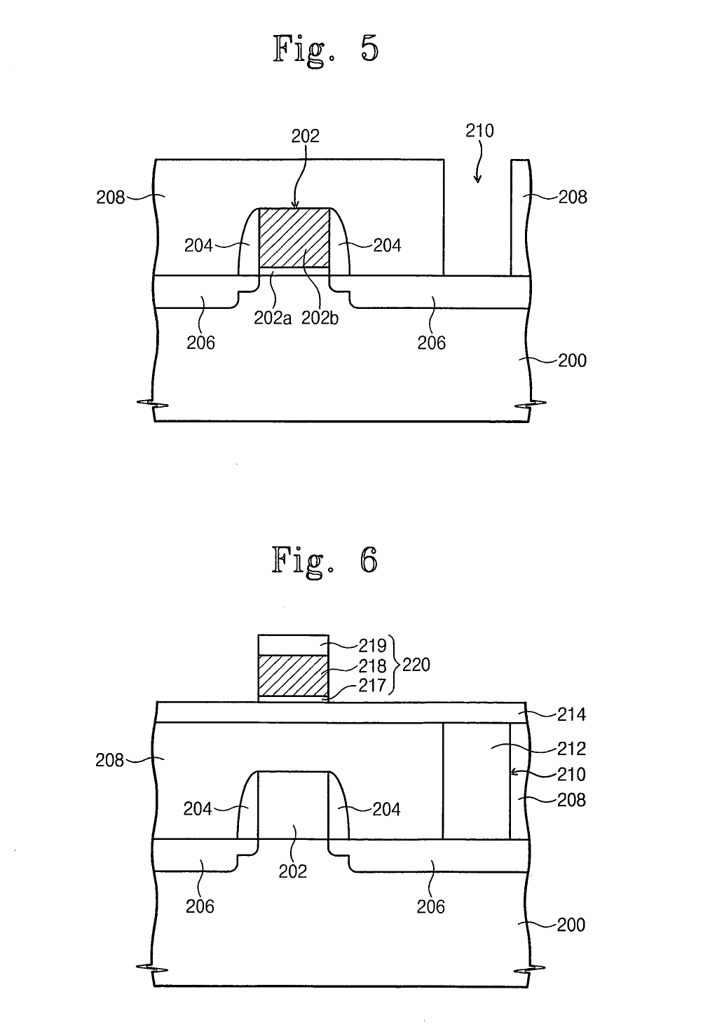

FIGS. 5 through 10 are cross-sectional views for describing a second embodiment of a method of forming a semiconductor device including a dopant-doped region according to another aspect of the present invention.

In the second embodiment, a semiconductor device including stacked transistors employing the aspect of the present invention will be described. This method of forming a semiconductor device can be applied to an SRAM device, for example, where a drive transistor and a load transistor are stacked. Of course, the method of forming the semiconductor device can also be applied to a semiconductor device including different types of stacked transistors.

Referring to FIG. 5, a lower gate pattern 202 is formed on a substrate 200, and a lower source/drain region 206 is formed at both sides of the lower gate pattern 202 in the substrate 200. Lower spacers 204 can be formed on both sidewalls of the lower gate pattern 202. The lower source/drain region 206 can be formed as an LDD source/drain region and/or an extended source/drain region, using the lower spacers 204. As with gate pattern 110 in FIG. 1, the lower gate pattern 202 includes a lower gate insulating layer 202a and a lower gate electrode 202b that are sequentially stacked. The lower gate pattern 202 can further include a lower capping insulating pattern (not shown) disposed on the lower gate electrode. The substrate 200 is a semiconductor substrate, for example, a silicon substrate. A lower transistor includes the lower gate pattern 202 and the lower source/drain region 206. For simplicity, in FIGS. 6 through 10 the details of the lower gate insulating layer 202a and a lower gate electrode 202b of gate pattern 202 are not shown.

An interlayer insulating layer 208 is formed on substantially an entire surface of the substrate 200 including the lower transistor. The interlayer insulating layer 208 can be formed as an oxide layer, for example. The interlayer insulating layer 208 is patterned to form a contact hole 201 exposing the lower source/drain region 206 at one side of the lower gate pattern 202.

Referring to FIG. 6, an epitaxial contact 212 filling the contact hole 210, and a semiconductor channel layer 214 disposed on the interlayer insulating layer 208 and contacting the epitaxial contact 212 are formed. Preferably, the semiconductor channel layer 214 is formed in a single crystalline state.

One embodiment of a method of forming the epitaxial contact 212 and the semiconductor channel layer 214 will now be described. First, an epitaxial growing process is performed to form the epitaxial contact 212 from the lower source/drain region 206 exposed by the contact hole 206. Specifically, the epitaxial contact 212 fills the contact hole 210, and has a top surface about as high as a top surface of the interlayer insulating layer 208. The epitaxial contact 212 is formed of a semiconductor in a single crystalline state. An amorphous semiconductor layer is formed on the interlayer insulating layer 208. The amorphous semiconductor layer contacts the top surface of the epitaxial contact 212. Thereafter, a solid-phase epitaxial process is performed on the substrate 200 to convert the amorphous semiconductor layer into a single crystalline state, thereby forming the semiconductor channel layer 214. The solid-phase epitaxial process is a process of performing a thermal treatment process on the amorphous semiconductor layer. Here, the top surface of the epitaxial contact 212 acts as a seed layer so that the amorphous semiconductor layer is converted into a single crystalline state.

Alternatively, the epitaxial contact 212 and the semiconductor channel layer 214 can be formed by another method. As for this alternative method, an epitaxial growing process is performed on the substrate 200, so that an epitaxial layer is formed from the lower source/drain region 206 exposed by the contact hole 210. Then, the epitaxial layer fills the contact hole 210, and is further formed on the interlayer insulating layer 208. The epitaxial layer is formed as a semiconductor of a single crystalline state. A top surface of the epitaxial layer might not be planar. Therefore, after the epitaxial layer is formed, a planarization process is preferably performed on the top surface of the epitaxial layer using a chemical mechanical polishing (CMP) process, as an example. A portion of the planarized epitaxial layer filling the contact hole 210 corresponds to the epitaxial contact 212, and a portion of the planarized epitaxial layer formed on the interlayer insulating layer 208 and contacting the epitaxial contact 212 corresponds to the semiconductor channel layer 214.

Thereafter, referring to FIG. 6, an upper gate pattern 220 is formed on the semiconductor channel layer 214. The upper gate pattern 220 includes an upper gate insulating layer 217, an upper gate electrode 218 and an upper capping insulating pattern 219 that are sequentially stacked. The upper gate insulating layer 217 can be formed of an oxide layer, particularly, a thermal oxide layer. The upper gate electrode 218 can be formed of at least one selected from a group comprising doped poly silicon, which is a conductive material, metal (e.g., tungsten, molybdenum, or the like), conductive metal nitride (e.g., titanium nitride, tantalum nitride, or the like), and metal silicide (e.g., tungsten silicide, cobalt silicide, or the like). The upper capping insulating pattern 219 can be formed of an oxide layer, a nitride layer or an oxide nitride layer, as examples.

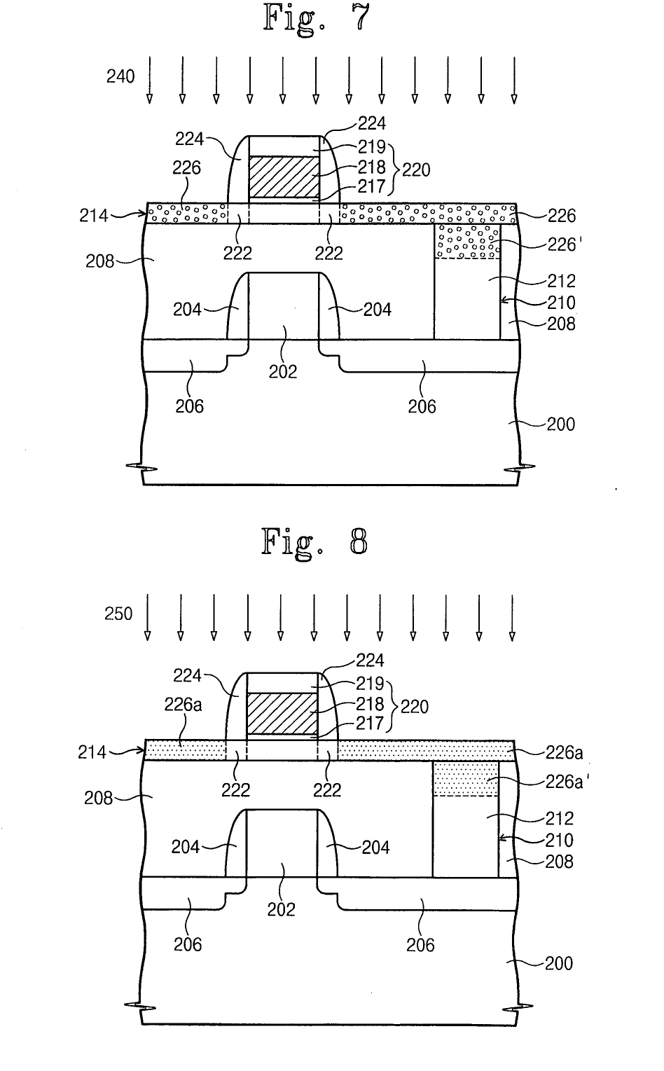

Referring to FIG. 7, first dopant ions are implanted into the semiconductor channel layer 214 using the upper gate pattern 220 as a mask to form a first dopant-implanted region 222. Upper spacers 224 are formed on both sidewalls of the upper gate pattern 220.

Lattice defect inducing element ions 240 are implanted into the semiconductor channel layer 214 using the upper gate pattern 220 and the upper spacer 224 as a mask to form a lattice defect region 226. Like the first embodiment described above, a plurality of vacancies and/or semiconductor atoms whose bonding forces are weakened are formed within the lattice defect region 226. When the lattice defect inducing element ions are implanted, a second lattice defect region 226′ can be formed in at least an upper portion of the epitaxial contact 212. The amount of lattice defects within the second lattice defect region 226′ formed in the epitaxial contact 212 can be smaller than that of the lattice defects within the first lattice defect region 226 formed in the semiconductor channel layer 214.

Preferably, the lattice defect inducing element ions 240 are of an element that is irrelevant to an electrical characteristic of a dopant-doped region. For example, preferably, the lattice defect inducing element is one selected from a group comprising silicon, carbon, nitrogen, fluorine germanium, and a combination thereof.

Referring to FIG. 8, second dopant ions 250 are implanted into the lattice defect regions 226 using the upper gate pattern 220 and the upper spacers 224 as a mask to form a second dopant-implanted region 226a. The second dopant ions occupy the vacancies within the lattice defect region 226 and are substituted for the semiconductor atoms having weakened bonding forces. Accordingly, as compared to the prior art, more second dopants can be substituted for the semiconductor atoms within the second dopant-implanted region 226a. The second dopant ions can be implanted even into the lattice defect region 226′ formed in the epitaxial contact 212. Accordingly, a second dopant-implanted region 226a′ can be formed in at least an upper portion of the epitaxial contact 212.

The second dopant ions can be n-type conductive ions such as arsenic (As) ions, phosphorous (P) ions, or the like, as examples. Alternatively, the second dopant ions can be p-type dopant ions such as boron ions or the like, as examples. In either case, the first dopant ions are the same type of dopants as the second dopants. Doses of the first dopant ions can be smaller than doses of the second dopant ions. In this case, the first dopant-implanted region 222 corresponds to a lightly doped region of an LDD source/drain region. The doses of the first dopant ions can be almost as high as those of the second dopant ions. In this case, the first dopant-implanted region 222 corresponds to an extended portion of an extended source/drain region.

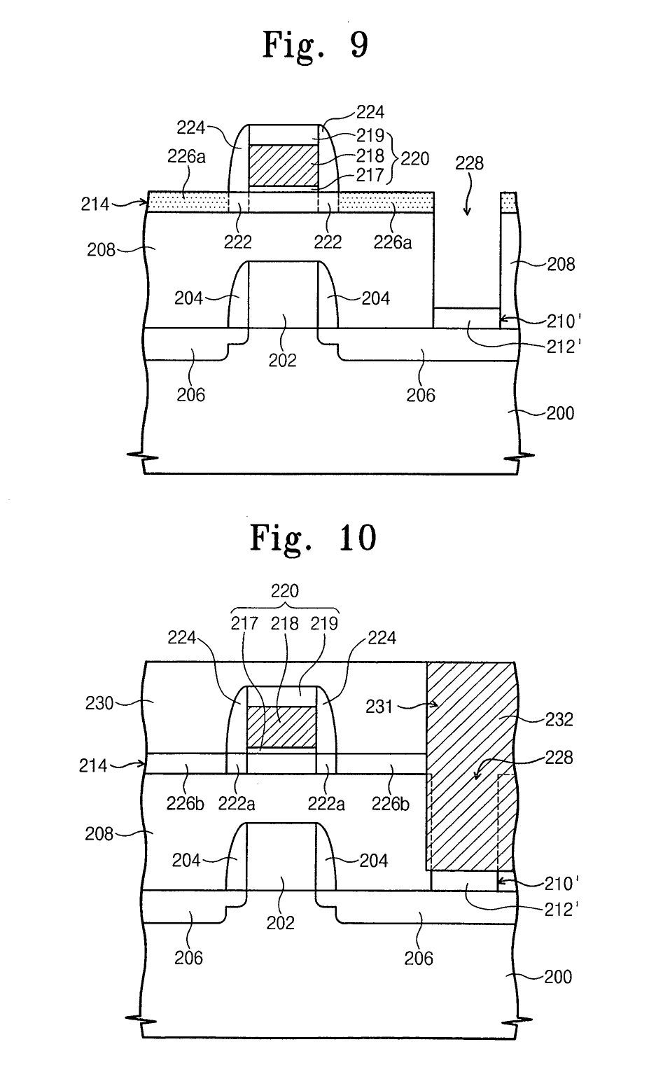

Referring to FIG. 9, the second dopant-implanted region 226′ is preferably removed from the epitaxial contact 212. Specifically, the second dopant-implanted region 226a formed in the semiconductor channel layer 214 on the epitaxial contact 212 and the second dopant-implanted region 226a′ formed in at least the epitaxial contact 212 are sequentially etched and removed. In such a manner, a recess region 228 is formed. The recess region 228 can be formed by selective exposure using a photoresist pattern or the like. Although the width of the recess region 228 is the same as that of the contact hole 210 in the drawing, the width of the recess region 228 can be greater than that of the contact hole 210. When the recess region 228 is formed, a lower portion 212′ of the epitaxial contact can remain to protect a recess in the lower source/drain region 206. Of course, the lower portion 212′ of the epitaxial contact can be removed. The reference numeral 210′ denotes a lower portion of the contact hole 210 where the lower portion 212′ of the epitaxial contact remains.

Referring to FIG. 10, after the second dopant-implanted region 226′ formed in the epitaxial contact 212 is removed, an annealing process is performed on the first and second dopant-implanted regions 222 and 226a to form first and second dopant-doped regions 222a and 226b, respectively. The first and second dopants within the first and second dopant-implanted regions 222 and 226a are activated by the annealing process, so that the first and second dopant-doped regions 222a and 226b are formed. The annealing process contributes to removing the lattice defects within the second dopant-doped region 226b. The annealing process can be a rapid thermal annealing process or a laser annealing process, as examples. The processes for forming the first dopant-implanted region 222 and the upper spacers can be omitted. Alternatively, the forming of the first dopant-implanted region can be omitted, but the forming of the upper spacer 224 can be performed after the forming of the second dopant-doped region 226b.

The first and second dopant-doped regions 222a and 226b can form an upper source/drain region. An upper transistor includes the upper source/drain region and the upper gate pattern 220.

The lower transistor can correspond to a drive transistor of an SRAM cell, and the upper transistor can correspond to a load transistor of the SRAM cell. In this case, the lower transistor is formed as an NMOS transistor, and the upper transistor is formed as a PMOS transistor. That is, the second dopant-doped region 226b can be doped with boron. As boron, whose activation level is relatively low as compared to arsenic and phosphorous, is implanted using the lattice defect region 226, the second dopant-doped region 226b having a large amount of activated boron can be implemented.

When the aspect of the present invention is applied to the semiconductor device including stacked transistors other than the SRAM cell, the upper transistor can be an NMOS transistor.

The following processes will now be described, taking as an example the case where the lower and upper transistors are included in the SRAM cell.

An upper insulating layer 230 filling the recess region 228 is formed on an entire surface of the substrate 200 having the second dopant-doped regions 226b. The upper insulating layer 230 covers the upper transistor. The upper insulating layer 230 can be an oxide layer, as an example.

At least the upper insulating layer 230 is patterned to form a node hole 231 overlapping the recess region 228, indicated by dashed lines. The node hole 231 exposes a side surface of the second dopant-doped region 226b, and the lower portion 212′ of the epitaxial contact. The node hole 231 can have a width greater than that of the recess region 228 and/or the contact hole 210. In this case, a portion of the interlayer insulating layer 208 can be etched when the node hole 231 is formed. A node contact 232 occupying the node hole 231 is formed. The node contact 232 electrically connects the second dopant-doped region 226b and the lower source/drain region 206. The node contact 232 is preferably formed of a metallic conductive material. For this reason, the lower source/drain region 206 and the second dopant-doped region 226b can be electrically connected to each other, although the lower source/drain region 206 and the second dopant-doped region 226b are doped with different types of dopants. For example, the node contact 232 can be formed of at least one of metal (e.g., tungsten, copper, titanium, tantalum, aluminum, or the like), and conductive metal nitride (e.g., titanium nitride, tantalum, or the like).

According to the method of forming the semiconductor device, the lattice defect region 226 including a plurality of vacancies and/or semiconductor atoms having weakened bonding forces is formed using the lattice defect inducing elements, and then the second dopant ions 250 are implanted thereinto. Thus, as compared to the prior art, much more second dopants can be substituted for the semiconductor atoms. As a result, the amount of dopants activated within the second dopant-doped region 226b greatly increases, and thus the second dopant-doped region can have an excellent electrical characteristic. Particularly, although boron having such a low activation level is used as the second dopants, the second dopant-doped region 226b having a sufficient amount of activated boron can be realized. Also, because the amount of inactivated second dopants within the second dopant-doped region 226b decreases, the defects can be reduced.

In accordance with this embodiment, a sufficient amount of activated dopants can be formed within the second dopant-doped region 226b without increasing a process temperature of the annealing process. Thus, the annealing process minimizes diffusion of the second dopants, so that the second dopant-doped region 226b can have a minimized size.

In this embodiment, before the annealing process, the second dopant-implanted region 226a formed in the semiconductor channel layer 214 on the epitaxial contact 212 and the second dopant-doped region 226a′ formed in the second epitaxial contact 212 are removed. Accordingly, diffusion of surplus elements (e.g., lattice defect inducing elements and/or surplus semiconductor atoms) between lattices can be prevented from occurring through the epitaxial contact 212. As a result, the movement of the dopants due to the diffusion of the surplus elements is prevented, so that the lower source/drain region 206 does not have a deep junction.

As described, according to the illustrative embodiments, lattice defect inducing element ions are implanted into a semiconductor channel layer before implantation of dopant ions. Thus, vacancies unoccupied by the semiconductor atoms of the semiconductor channel layer can be formed, and/or bonding forces of the semiconductor atoms can be weakened. As a result, the amount of activated dopants can increase. Particularly, the amount of dopants activated within the dopant-doped region can increase even when a process temperature of an annealing process is limited. Consequently, a dopant-doped region optimized for high integration is formed, so that a highly integrated semiconductor device can be formed.

It will be apparent to those skilled in the art that various modifications and variations can be made across various embodiments, without departing from the spirit and scope of the present invention. It is, therefore, understood that the invention can be implemented in various forms and embodiments, and that they can be applied in numerous applications, only some of which have been described herein. It is intended by the following claims to claim that which is literally described and all equivalents thereto, including all modifications and variations that fall within the scope of each claim.

What is claimed is:

1. A method of forming a semiconductor device, the method comprising:
implanting lattice defect inducing element ions into a semiconductor channel layer of a substrate to form a lattice defect region;
implanting dopant ions into the lattice defect region to form a dopant-implanted region; and
performing an annealing process on the dopant-implanted region to form a dopant-doped region.

2. The method of claim 1, wherein the lattice defect inducing element ions are of an element that is irrelevant to an electrical characteristic of the dopant-doped region.

3. The method of claim 2, wherein the lattice defect inducing element is one selected from the group comprising silicon, carbon, nitrogen, fluorine, germanium, and a combination thereof.

4. The method of claim 1, wherein the substrate includes a semiconductor substrate, a buried insulating layer and a semiconductor channel layer that are sequentially stacked.

5. The method of claim 1, further comprising forming a gate pattern including a gate insulating layer and a gate electrode that are sequentially stacked on the semiconductor channel layer,
wherein the lattice defect inducing element ions are implanted using the gate pattern as a mask, and the lattice defect region is formed at both sides of the gate pattern in the semiconductor channel layer.

6. The method of claim 5, further comprising forming spacers on both sidewalls of the gate pattern before the forming of the lattice defect region,
wherein the lattice defect inducing element ions are implanted using the gate pattern and the spacers as a mask.

7. A method of forming a semiconductor device, the method comprising:
forming an interlayer insulating layer on a substrate;
forming a semiconductor channel layer on the interlayer insulating layer;
forming a gate pattern including a gate insulating layer and a gate electrode that are sequentially stacked on the semiconductor channel layer;
implanting lattice defect inducing element ions into the semiconductor channel layer using the gate pattern as a mask to form a lattice defect region;
implanting dopant ions into the lattice defect region using the gate pattern as a mask to form a dopant-implanted region; and
performing an annealing process on the substrate having the dopant-implanted region to form a dopant-doped region.

8. The method of claim 7, wherein the lattice defect inducing element ions are of an element that is irrelevant to an electrical characteristic of the dopant-doped region.

9. The method of claim 8, wherein the lattice defect inducing element is one selected from the group comprising silicon, carbon, nitrogen, fluorine, germanium, and a combination thereof.

10. The method of claim 7, wherein the dopant ions are boron ions.

11. The method of claim 7, further comprising forming spacers on both sidewalls of the gate pattern before the forming of the lattice defect region,
wherein the lattice defect inducing element ions are implanted using the gate pattern and the spacers as a mask.

12. The method of claim 7, further comprising:
patterning the interlayer insulating layer to form a contact hole exposing a predetermined region of the substrate; and
forming an epitaxial contact filling the contact hole and contacting the substrate and the semiconductor channel layer, the semiconductor channel layer being formed in a single crystalline state.

13. The method of claim 12, wherein the lattice defect region is further formed at an upper portion of the epitaxial contact, and the method further comprising, before the performing of the annealing process, removing the semiconductor channel layer on the epitaxial contact and at least the upper portion of the epitaxial contact to form a recess region.

14. The method of claim 13, further comprising:
forming an upper insulating layer on an entire surface of the substrate having the dopant-doped region, the upper insulating layer filling the recess region; and
forming a node contact penetrating at least the upper insulating layer and overlapping the recess region, the node contact being electrically connected to a side surface of the dopant-doped region and the substrate exposed by the contact hole.

15. The method of claim 12, wherein the forming the semiconductor channel layer comprises:
forming an amorphous semiconductor channel layer on the interlayer insulating layer, the amorphous semiconductor channel layer contacting the epitaxial contact; and
performing a thermal treatment on the amorphous semiconductor channel layer to form the semiconductor channel layer of a single crystalline state.

16. The method of claim 12, wherein the forming of the epitaxial contact and the semiconductor channel layer comprises:
forming a single crystalline epitaxial layer by an epitaxial growing process, the signal crystalline epitaxial layer filling the contact hole and covering the interlayer insulating layer; and
planarizing an upper surface of the epitaxial layer,
wherein a portion of the planarized epitaxial layer that fills the contact hole is the epitaxial contact, and a portion of the planarized epitaxial layer that is disposed on the interlayer insulating layer and contacts the epitaxial contact is the semiconductor channel layer.

17. The method of claim 12, further comprising, before the forming of the interlayer insulating layer:
forming a lower gate pattern on the substrate; and
forming lower source/drain regions at both sides of the lower gate pattern in the substrate,
wherein the interlayer insulating layer covers the lower gate pattern and the lower source/drain regions, and the contact hole exposes the lower source/drain regions.

18. The method of claim 17, wherein the lower gate pattern and the lower gate source/drain regions comprise a lower transistor corresponding to a drive transistor of an SRAM cell, and the gate pattern and the dopant-doped region comprise an upper transistor corresponding to a load transistor of the SRAM cell.
